(19) United States
(12) Patent Application Publication
(10) Pub. No.: US 2018/0270993 A1
(43) Pub. Date: Sep. 20, 2018

(54) COOLING USING A WICK WITH VARIED THICKNESS

(71) Applicant: Intel Corporation, Santa Clara, CA (US)

(72) Inventors: Devdatta P. Kulkarni, Portland, OR (US); Sandeep Ahuja, Portland, OR (US)

(21) Appl. No.: 15/462,261

(22) Filed: Mar. 17, 2017

(51) Int. Cl. H05K 7/20; F28D 15/04

(52) U.S. Cl. CPC H05K 7/20818; F28D 15/046; H05K 7/20336; H05K 7/20318; H05K 7/20309

(57) ABSTRACT

Embodiments described herein may include apparatuses, systems and/or processes to provide an evaporator including a chamber to receive condensate flow from an input end and output a vapor outflow at an output end with a wick, heated by a surface of the chamber, having variable thickness within the chamber to receive condensate, where the thickness of the wick proximate to the condensate inflow is greater than the thickness of the wick proximate to the vapor outflow. Other embodiments may be described and/or claimed.

### FIELD

Embodiments of the present disclosure generally relate to the fields of computing and electronic systems. More specifically, embodiments of the present disclosure relate to cooling components in a computing or electronic system.

### BACKGROUND

As components of computing or electronic systems decrease in size and increase in power requirements, cooling individual components as well as collections of components will become increasingly important to ensure proper system function moving forward. For example, the size of central processing unit (CPU) dies are miniaturizing at the same time the number of cores, heat dissipation, and thermal design power (TDP) of these dies are increasing. This can result in a higher heat flux from the CPU dies and increase the challenge for thermally managing the CPU.

There exist a few legacy implementations for passive air cooled solutions using phase change mechanisms. One example may be the use of heat pipes. Heat pipes may be embedded in the base of a heat sink to better spread heat across the base or may be placed in the base and then fins may be attached to the heat pipes for heat dissipation. These legacy examples may be implemented in a 1U and 2U configuration, and may be used in server and/or workstation implementations.

Other legacy examples may include a heat pipe-based tower heat sink, where heat pipes may be oriented against the base of the heat sink with fins attached to the heat pipes that may be oriented perpendicular to the heat pipes. In addition, heat pipes may be placed in the base of an evaporator to carry heat to one or more protruded areas where the heat is dissipated using fins in the protruded areas. Remaining heat may be transferred via fins attached to the evaporator itself. These legacy examples may be used in desktops, high-power workstations, or in servers.

Other legacy examples may include the use of a vapor chamber. A vapor chamber may be a cavity with a wick inside the chamber that is part of a fluid loop, with an evaporator and a condenser coupled with the vapor chamber cavity. A processor may be thermally coupled with the vapor chamber. Other legacy examples may include a loop heat pipe with an air cooled condenser, where an evaporator may be positioned on the base plate of the heat sink and heat pipes in the form of tubes may be routed to other places for heat dissipation from a processor.

One disadvantage of these implementations may include the inability to reliably load the processor with the vapor chamber attached into a processor socket on a motherboard. For example, as the socket load goes higher, the vapor chamber may not have sufficient rigidity to be part of the socket loading process. In addition, in legacy implementations, the heat carrying capacity of the heat sinks may be limited due to the diameter of the heat pipes, for example, 6 millimeters (mm).

Other disadvantages may include the ability to maintain heat sink keep out volumes (KOVs) for processors. For example, as the diameter of a heat pipe increases, heat capacity may increase, but at the same time the bending radius of pipes increases and poses a challenge for fin placement within a compact KOV area. In addition, the placement of these heat pipes for high-powered dies while maintaining KOVs for the processor may become more difficult.

Another disadvantage with legacy air cooled solutions such as 1U copper (Cu)/aluminum (Al) heat sinks or 2U heat pipe based heat sinks may include not meeting the target case or junction temperature requirements with existing system level boundary conditions. In addition, challenges may exist with the emergence of high-power dies on multi-chip packages (MCP) cooled using legacy heat-pipe based heat sinks that may not be able to meet the heat flux requirements.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1 illustrates a side view of an example implementation of a loop heat pipe (LHP) heat sink, in accordance with various embodiments.

FIG. 2 illustrates a front view of an example implementation of an LHP heat sink, in accordance with various embodiments.

FIG. 3 illustrates multiple side views of an example implementation of an LHP heat sink, in accordance with various embodiments.

FIG. 4 illustrates a front view of an example implementation of an LHP heat sink with extended fins, in accordance with various embodiments.

FIG. 5 illustrates a side view of an example implementation of an LHP heat sink with extended fins, in accordance with various embodiments.

FIG. 6 illustrates a block diagram of a process for implementing an LHP heat sink, in accordance with various embodiments.

### DETAILED DESCRIPTION

Embodiments described herein may include apparatuses, systems and/or processes to provide an air cooled heat sink based on LHP technology to cool processors with high thermal removal requirements under restrictive platform level air-flow boundary conditions. Examples of these processors may include processors in the Intel® Xeon® and Xeon Phi™ product families. These, and other similar processors, would benefit from new thermal removal technologies that fulfill thermal removal requirements without impacting the board level components layout or maintaining heat sink KOVs for those processors.

Embodiments of the LHP-based heat sink described herein may facilitate achieving cooling targets, in particular for processors with high thermal removal requirements under restrictive platform level air-flow boundary conditions. Also, due to the typical large number of pin contacts at the socket for these processors, providing socket loading through heat sink (processor heat sink loading mechanism (PHLM)) may be very important for the installation and proper operation of the processors. LHP embodiments described herein may provide the additional stiffness necessary for heat sinks with the PHLM in particular due to the presence of a wick and structural ribs inside the evaporator chamber. In addition, the additional structural support may give a chance to reduce base thickness of the heat sink and hence an overall reduction in weight and/or an overall increase in thermal performance.

In addition, advantages of embodiments of LHP may be due at least in part to an internal wick structure within the evaporation chamber, structural rigidity from the walls of the multiple evaporator chambers, increased overall heat carrying capability, smaller diameter heat pipes, the absence of wick material in heat pipes, ability to implement a wider and taller heat sink, and increased wick area coverage on the base evaporator chambers within the heat sink. These advantages may result in a compact, high performance heat sink with the same KOV as 1U and/or 2U heat pipe heat sink with an increased heat flux capability. In embodiments, there may be only one wick in an LHP/evaporation chamber combination, and that wick may be in the evaporation chamber.

In addition, embodiments of the LHP heat sink may include the attachment of fins directly to the evaporator. As a result, cooling of the processors, for example, when in idle power mode, may happen directly through the fins by conducting heat from the evaporator to the fins and dissipating heat to ambient air by natural convection and may not require any minimum heat flux for the LHP to operationally function. For example, attaching fins directly to the evaporator may dissipate a heat load from a processor that is below a minimum heat load that may be needed to start operating the LHP. In this example, the temperature of the processor in idle power conditions may slowly creep up and may shut down the server associated with the processor in the absence of airflow and before the LHP may start operation.

In embodiments, rotation of the heat sink to align fin layout with respect to incoming airflow may not be necessary due in part to increased performance due to coverage of a larger wick in the evaporator chambers that covers more area. In embodiments, the integrated gradient wick with supporting ribs in the evaporator and fins may create an LHP form factor that may have the same or similar form factor as a legacy server or desktop air cooled heat sink.

Embodiments of the LHP heat sink cooling apparatus may be coupled to a heat sink, for example, a processor that may include a multi-core processor, that is seated on a circuit board. In embodiments, the circuit board may be coupled to a mechanism to facilitate use in a rackmount system. For example, the circuit board may be a motherboard that is coupled with a sled or some other rack mounting mechanism that may facilitate the circuit board insertion and/or securing into the rackmount system for operation.

In the following description, various aspects of the illustrative implementations are described using terms commonly employed by those skilled in the art to convey the substance of their work to others skilled in the art. However, it will be apparent to those skilled in the art that embodiments of the present disclosure may be practiced with only some of the described aspects. For purposes of explanation, specific numbers, materials, and configurations are set forth in order to provide a thorough understanding of the illustrative implementations. However, it will be apparent to one skilled in the art that embodiments of the present disclosure may be practiced without the specific details. In other instances, well-known features are omitted or simplified in order not to obscure the illustrative implementations.

In the following description, reference is made to the accompanying drawings that form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “including,” “having,” and the like, as used with respect to embodiments of the present disclosure, are synonymous.

The terms “coupled with” and “coupled to” and the like may be used herein. “Coupled” may mean one or more of the following. “Coupled” may mean that two or more elements are in direct physical, thermal or electrical contact. However, “coupled” may also mean that two or more elements indirectly contact each other, but yet still cooperate or interact with each other, and may mean that one or more other elements are coupled or connected between the elements that are said to be coupled with each other. By way of example and not limitation, “coupled” may mean two or more elements or devices are coupled by electrical connections on a printed circuit board such as a motherboard, for example. By way of example and not limitation, “coupled” may mean two or more elements or devices are thermally coupled. By way of example and not limitation, “coupled” may mean two or more elements/devices cooperate and/or interact. By way of example and not limitation, a computing apparatus may include two or more computing devices “coupled” on a motherboard or by one or more network linkages.

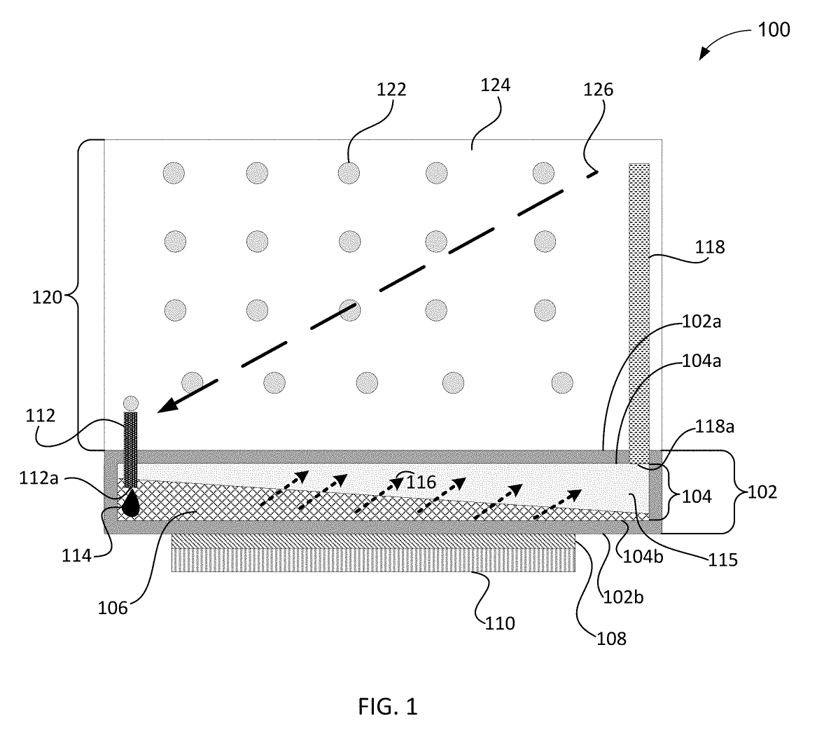

FIG. 1 illustrates a side view of an example implementation of an LHP heat sink, in accordance with various embodiments. Diagram 100 shows a side view of an evaporator 102 that includes an evaporator chamber 104. A wick 106 may be disposed proximate to evaporator chamber floor 104b which, in embodiments, may be proximate to and/or thermally coupled to the evaporator floor 102b. In embodiments, the evaporator ceiling 102a may be opposite the evaporator floor 102b, and the evaporator chamber ceiling 104a may be opposite the evaporator chamber floor 104b. In embodiments, the evaporator floor 102b may be proximate to and/or thermally coupled to a processor 110. In embodiments, the processor 110 may be a high-performance processor and/or an MCP, with high thermal removal requirements under restrictive platform level air-flow boundary conditions. In embodiments, a thermal interface material (TIM) 108 that may have properties of thermal conductivity and adhesion may be between the processor 110 and the evaporator floor 102b.

In embodiments, the wick 106 may cover all or nearly the entire evaporator chamber floor 104b. This may allow efficient heat transfer from all or nearly all of a surface area of a heat source, for example, processor 110, proximate to the evaporator floor 102b. In embodiments, coverage of the wick 106 may provide direct cooling for every die on an MCP. In embodiments, the wick 106 may be made of a sintered material or of some other suitable material.

In embodiments, condensate 114 may enter the evaporator chamber 104 as condensate inflow from an input end 112a of an input pipe 112. In embodiments, the condensate 114 may be water, R245fa, methanol, or some other suitable substance. The selection of the substance may be based upon a desired temperature range and/or a heat carrying capacity. In embodiments, during operation the condensate 114 within the wick 106 may boil, or otherwise change state or change phase, when the heat of the evaporator chamber floor 104b becomes sufficiently hot and heats the condensate 114 to create vapor 116. In embodiments, the vapor 116 may build within vapor chamber 115 within the evaporator chamber 104. The vapor 116 may then cause an increase in pressure in the vapor chamber 115, which may facilitate flow of the vapor 116 as vapor outflow into an output end 118a of output pipe 118. The vapor 116 may then travel through the output pipe 118 and into a condenser 120. In embodiments, the diameter of the output pipe 118 may be larger than the diameter of the input pipe 112 to facilitate vapor flow into the condenser 120.

In embodiments, the wick 106 may be thicker near the input end 112a than it is near the output end 118a. In embodiments, the wick 106 may have a gradient structure as shown in FIG. 1, and/or may get thinner from the input end 112a to the output end 118a. In embodiments, this gradient structure may cause the vapor chamber 115 to have a higher volume near the output end 118a than it has near the input end 112a. This may result in a higher pressure of vapor 116 near the output end 118a to facilitate vapor outflow through output pipe 118.

In embodiments, the condenser 120 may include a heat pipe 122 that may be connected to the output pipe 118 and the input pipe 112. In embodiments, the connected heat pipe 122 may form a closed system that includes the evaporator chamber 104, the output pipe 118, and the input pipe 112. In embodiments, the heat pipe 122 may be a plurality of heat pipes. In embodiments, the vapor 116 may enter the heat pipe 122 from the output pipe 118. As the vapor 116 travels towards the input pipe 112, the vapor 116 may lose heat. In embodiments, the heat pipe 122 may not contain a wick.

As a result, the vapor 116 may change phase, change state, and/or condense, creating the condensate 114 that may continue to flow through the heat pipe 122 to the input end 112a, where the condensate 114 may enter the wick 106. In embodiments, this condensation may be also described as the vapor 116 turning into a saturated fluid. In embodiments, dashed arrow 126 may show the general direction of vapor 116/condensate 114 flowing through the heat pipe 122 from the output pipe 118 to the input pipe 112 as it returns to the evaporator 102. In embodiments, there may be no wick structure in the heat pipe 122 or in output pipe 118.

In embodiments, the routing pattern of the heat pipe 122 may not depend on gravity for the operation of the loop heat pipe or the flow of the vapor and/or condensate through the heat pipe 122 due to the pressure of the vapor 116 in the vapor chamber 115. In embodiments, the LHP may use gravity to assist in the return of the condensate 114 to the evaporator chamber 104. In embodiments, an LHP may be designed as described above to operate independently of gravitational forces.

The heat pipe 122 may be thermally coupled to a fin 124. In embodiments, the heat pipe 122 may be soldered to the fin 124. In embodiments, the thermal coupling may accelerate heat dissipation from the vapor 116 in the heat pipe 122. In embodiments, heat in the fin 124 may be dissipated to the ambient air surrounding the fin 124. In embodiments, the fin 124 may be made of copper, aluminum, and/or some other suitable material or alloy.

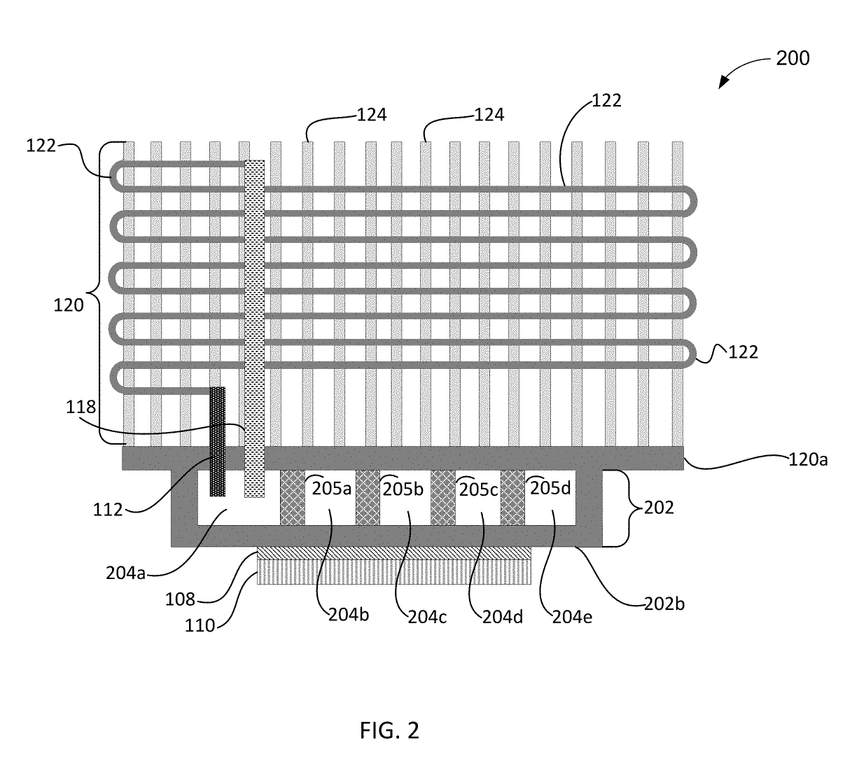

It should be noted that FIG. 1 shows a side view where a single fin 124 is shown, and where the heat pipe 122 intersects the fin 124 substantially perpendicularly to the fin 124. In embodiments, there may be a plurality of fins, as described below for FIG. 2. In embodiments, the fin 124, or a plurality of fins similar to the fin 124, may be thermally coupled to the evaporator 102. In embodiments, there may be a direct physical connection between the fin 124 and the evaporator 102. This may allow the fin 124 to dissipate heat directly from the evaporator 102. In embodiments, this may allow heat dissipation to occur prior to any minimum heat flux required for the LHP process to begin operating to dissipate heat through the heat pipes 122.

FIG. 2 illustrates a front view of an example implementation of an LHP heat sink, in accordance with various embodiments. Diagram 200 shows a plurality of fins 124 that may be thermally coupled to a heat pipe 122. In embodiments, the heat pipe 122 may be thermally coupled to the fins 124 either vertically or horizontally depending on the application of the LHP, for example, in a server versus in a workstation. In embodiments, during operation of the LHP, heat may be dissipated to the ambient air via the fins 124. In embodiments, the orientation of the fins 124 may be vertical or horizontal. In embodiments, the height of the fins 124 may be approximately the height of a 1U, 2U or tower heat sink. In embodiments, this height may depend upon the heat load and/or available space for the condenser 120.

The heat pipe 122 may be coupled to an input pipe 112 and output pipe 118 that are connected with evaporator chamber 204a, which may be similar to the evaporator chamber 104 of FIG. 1. In embodiments, the evaporator chamber 204a may be a closed system. In embodiments, evaporator 202, which may be similar to evaporator 102 of FIG. 1, may contain multiple evaporation chambers 204a-204e. In embodiments, each of the multiple evaporation chambers 204a-204e may be its own closed loop system having the input pipe 112, the heat pipe 122, the output pipe 118, wick (not shown) such as the wick 106 of FIG. 1, and condensate (not shown) such as the condensate 114 of FIG. 1. In embodiments, the closed loop may be completely evacuated and/or be under a vacuum.

In embodiments, one or more of the multiple evaporation chambers 204a-204e may be combined to create a closed loop system (not shown). In these embodiments, there may be one or more input pipes, heat pipes, output pipes, and/or wicks (not shown) to support the operation of the closed loop system served by one or more of the multiple evaporation chambers 204a-204e.

In embodiments, walls 205a-205d of the multiple evaporation chambers 204a-204e may be strengthened to serve as supporting ribs to provide structural stability between the condenser 120 and the evaporator 202. In embodiments, a plate 120a may serve as the top of multiple evaporation chambers 204a-204e, and may also serve as a base plate for the condenser 120. In embodiments, plate 120a may be made of aluminum, some other metal, or some other alloy that may conduct thermal energy. The walls 205a-205d may couple with the evaporator floor 202b, which may be similar to evaporator floor 102b of FIG. 1.

In embodiments, the evaporator floor 202b may be physically and/or thermally coupled with the processor 110. In embodiments, a TIM 108, which may thermally and/or adhesively couple the evaporator floor 202b with processor 110, may also be used.

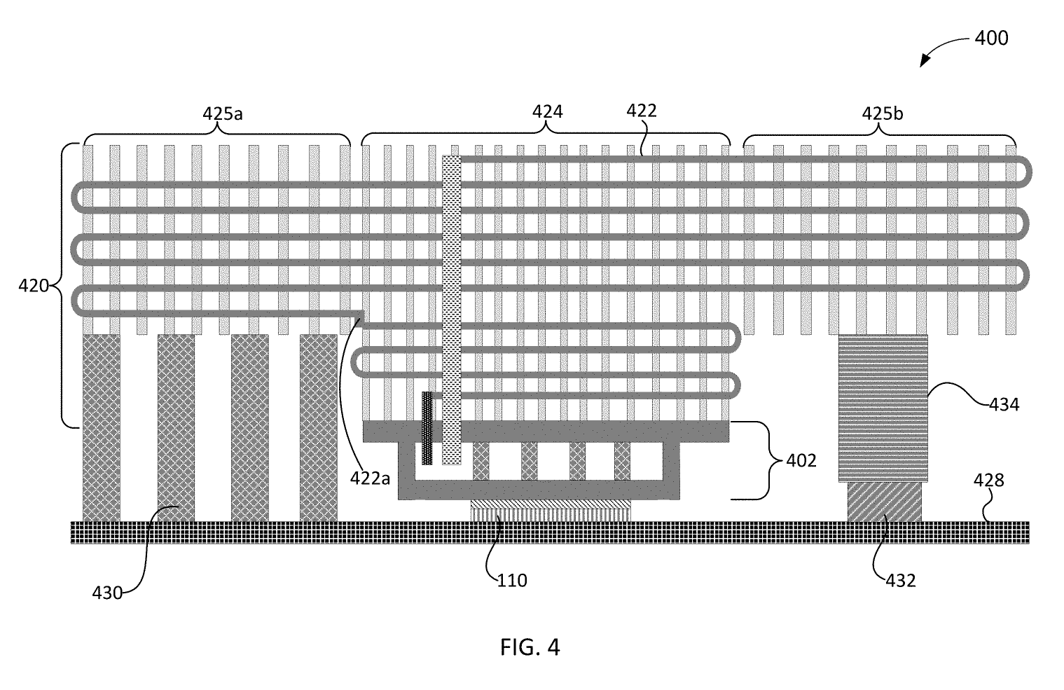

In embodiments, using the structures and elements discussed above, the condenser 120, the evaporator 202, and the processor 110 may be rigidly coupled into a unit as shown in diagram 200 that may be inserted into a socket on a motherboard such as motherboard 428 of FIG. 4. In embodiments, a rigid coupling may include a coupling of components such that the components cannot move relative to one another, and may have structural integrity with respect to each other. For example, the condenser 120, the evaporator 202, and the processor 110, when rigidly coupled, may be treated as a unit 200 so that the process of seating processor 110 into a motherboard may involve applying pressure on the condenser 120 or the evaporator 202 during the seating process.

In embodiments, performance of the LHP may have a heat carrying capacity that may be based on the configuration of the condenser 120. In embodiments, the LHP may be able to reach a 300 watt capacity using 4 mm diameter heat pipes 122, in contrast to legacy heat pipes (not shown) having a 6 mm diameter with 65 W heat carrying capacity.

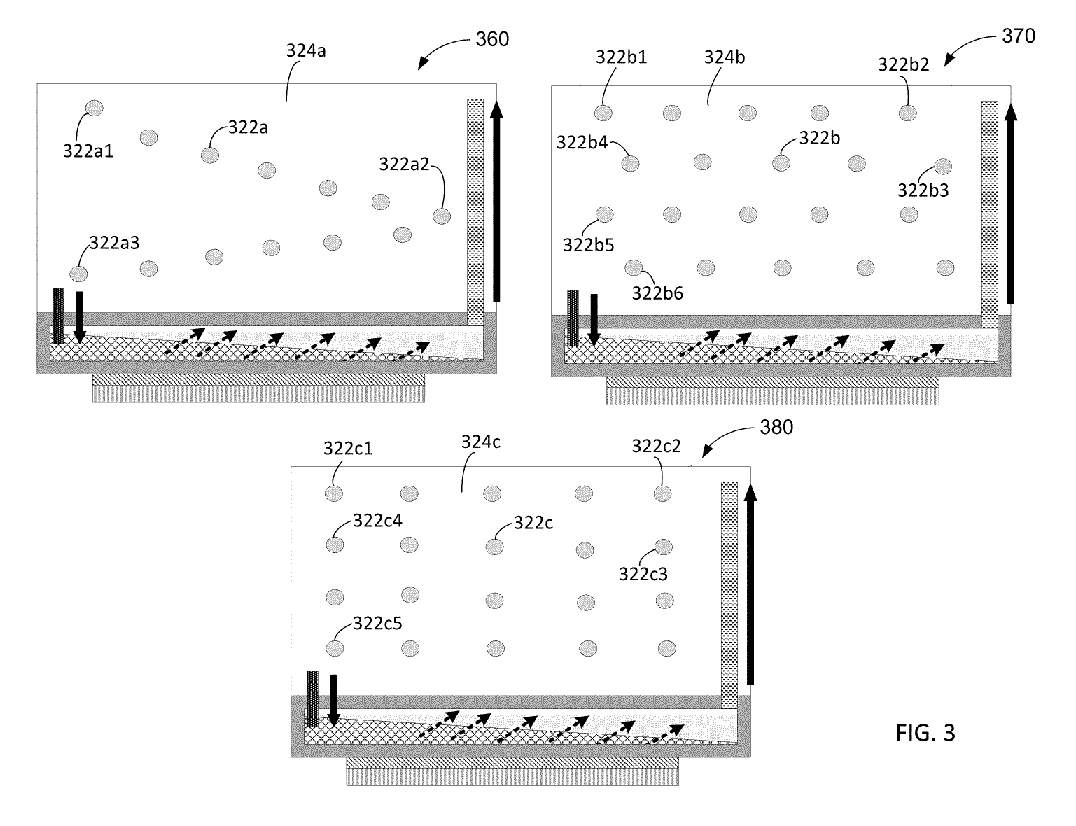

FIG. 3 illustrates multiple side views of an example implementation of an LHP heat sink, in accordance with various embodiments. Diagram 360, 370, and 380 show various, but non-limiting, examples of tube routing configurations of heat pipes using a side view of an evaporator such as evaporator 102 of FIG. 1.

One example, as shown in diagram 360, shows a heat pipe routing as the heat pipe 322a passes through a fin 324a, which may be similar to fin 124 of FIG. 1. In this example, the heat pipe may start at the upper left position 322a1, and as it winds through it may proceed diagonally across and down the fin 324a to a center position 322a2, and then may continue to wind through to the lower left position 322a3.

A second example, as shown in diagram 370, shows a heat pipe routing as the heat pipe 322b passes through fin 324b. In this example, the heat pipe 322b may start at the upper left position 322b1, proceed laterally to the upper right position 322b2, proceed down a level to position 322b3, proceed laterally to the left to position 322b4, proceed down a level to position 322b5, and then may continue on in a similar fashion to wind through to the lower left position 322b6. As shown, the pattern made by the heat pipe 322b as it passes through fin 324b may form a series of offset rows.

A third example, as shown in diagram 380, shows a heat pipe routing as the heat pipe 322c passes through a fin 324c. In this example, the heat pipe 322c may start at the upper left position 322c1, proceed laterally to the upper right position 322c2, proceed down a level to position 322c3, proceed laterally to the left to position 322c4, and then may continue on in a similar fashion to wind through to the lower left position 322c5.

In embodiments, the various patterns of heat pipes 322a, 322b, 322c shown in diagrams 360, 370, and 380, as well as other patterns not shown, may be selected based upon heat dissipation requirements based on various fin 324a, 324b, 324c materials, anticipated airflow patterns, and the like.

FIG. 4 illustrates a front view of an example implementation of an LHP heat sink with extended fins, in accordance with various embodiments. Diagram 400 shows a condenser 420, which may be similar to the condenser 120 of FIG. 2, coupled to an evaporator 402, which may be similar to the evaporator 202 of FIG. 2. The evaporator 402 may be thermally coupled to the processor 110, which may be plugged into a socket (not shown) attached to the motherboard 428.

The condenser 420 may include fins 424, which may be similar to the fins 124 of FIG. 2. In embodiments, an extended group of fins 425a, 425b that may extend beyond the footprint of the evaporator 402, which may be similar to the evaporator 102 of FIG. 1, may be coupled with the non-extended group of fins 424 that are within the footprint of the evaporator 402. In embodiments, extending fins 425a, 425b may increase the heat carrying capacity of the LHP heat sink. In embodiments, the extended groups of fins 425a, 425b may be added in any direction. In embodiments, fin configurations may cover both the X and Y dimensions of the motherboard 428, and in embodiments may form an umbrella-shaped heat sink.

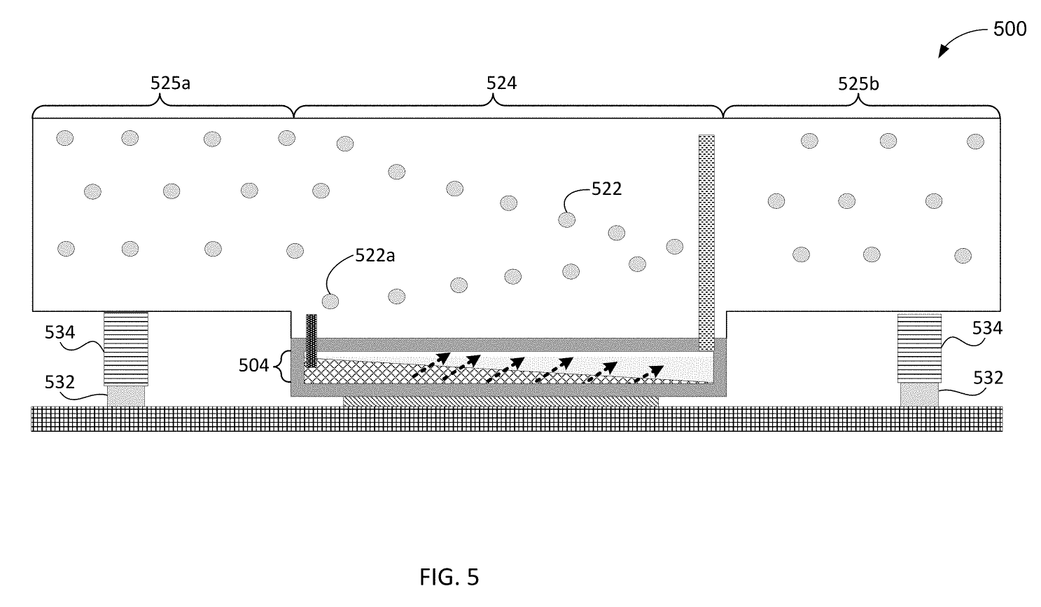

In embodiments, heat pipe 422, which may be similar to heat pipe 122 of FIG. 1, may pass through and be thermally coupled to fins 425a, 424, 425b in a variety of patterns as may be suitable for thermal energy conductivity. A non-limiting example of these patterns is discussed further in FIGS. 3 and 5.

In embodiments, the extended groups of fins 425a, 425b may facilitate cooling on top of other motherboard 428 components such as memory dual in-line memory modules (DIMMs) 430 or voltage regulators (VR) 432. In embodiments, the components such as the VR 432 may be attached to a heat sink 434. In embodiments, these components 430, 432 and/or heat sinks 434 associated with the components may or may not be thermally coupled with the fins 424.

A heat pipe 422, which may be similar to the heat pipe 122 of FIG. 2, may be thermally coupled to the non-extended group of fins 424 and the extended group of fins 425a, 425b. In embodiments, the heat pipe 422 may be multiple heat pipes. In embodiments, the extended group of fins 425a, 425b may be constructed in a modular form with one or more heat pipes (not shown) previously thermally coupled to the fins 425a, 425b. In embodiments, this extended group of fins 425a, 425b may be attached to the outer fins of the non-extended group of fins 424 using a Y coupler (not shown) or thick Y-shaped fin able to support the extended group of fins 425a, 425b. In embodiments, this may be done by directly soldering or brazing pipes to the non-extended group of fins 424. A bend radius may be used to divert the vapor from one fin group to another.

In embodiments, the LHP heat sink width may grow above the DIMMs 430 and/or the VR 432 in a T-shaped shared heat sink and maintain effective heat transfer through the extended group of fins 425a, 425b. Heat pipes for modular units of the extended groups of fins 425a, 425b may be coupled using a heat pipe coupling 422a.

FIG. 5 illustrates a side view of an example implementation of an LHP heat sink with extended fins, in accordance with various embodiments. Diagram 500 may show fins 525a, 524, 525b, which may be similar to fins 425a, 424, 425b of FIG. 4, that may be coupled together and may include a heat pipe 522, which may be similar to heat pipe 422 of FIG. 4, that may pass through the coupled fins to dissipate heat from the heat pipe. In embodiments, the vapor may condense within heat pipe 522 as the fins 525a, 524, 525b absorb heat. As a result, condensate may appear at a point within the heat pipe 522a that may be proximate to the evaporator chamber 504, which may be similar to the evaporator chamber 104 of FIG. 1.

As shown in diagram 500 fin extensions 525a, 525b may be thermally coupled to a voltage regulator 532 and its associated heat sink 534. In embodiments, the fin extensions 525a, 525b may absorb thermal energy from the heat sink 534, and may release that energy into the vapor/condensate within the heat pipe 522 that may then be transferred to another one of the fins 525a, 524, 525b.

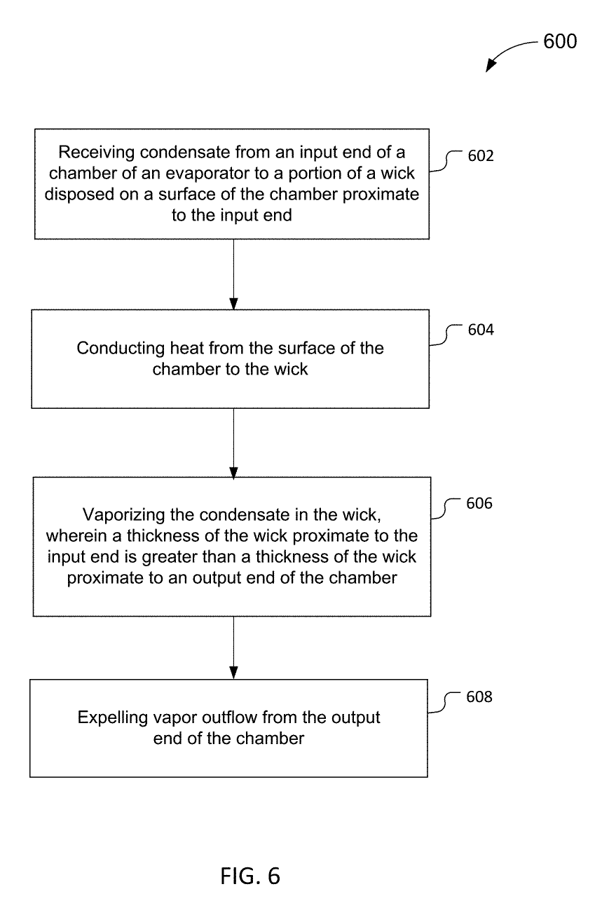

FIG. 6 illustrates a block diagram of a process for operating an LHP heat sink, in accordance with various embodiments. Process 600 may be implemented using the condenser 120, the evaporator 102, the evaporator chamber 104, an input pipe 112 having an input end 112a, the wick 106 that may hold the condensate 114, the vapor 116 that may fill the vapor chamber 115 within the evaporator chamber 104, and the output pipe 118 having the output end 118a that the vapor 116 may flow out of, from FIG. 1.

At block 602, the process may include receiving condensate from an input end of a chamber of an evaporator to a portion of a wick disposed on a surface of the chamber proximate to the input end. In embodiments, the condensate 114 may enter the wick 106 from the input end 112a of the input pipe 112 of FIG. 1. In embodiments, the condensate 114 may be any suitable fluid used for heat carrying, which may include water, R245fa, methanol, or some other composition depending on the requirements for temperature range and/or heat carrying capacity. In embodiments, the wick 106 may be made of sintered material, or may be made of some other suitable material.

At block 604, the process may include conducting heat from the surface of the chamber to the wick. In embodiments, heat from the operation of the processor 110 may flow through thermal conductivity to the evaporator chamber floor 104b of evaporator chamber 104. The wick 106 may be in contact with all or part of the heated evaporator chamber floor 104b of FIG. 1.

At block 606, the process may include vaporizing the condensate in the wick, wherein a thickness of the wick proximate to the input end is greater than a thickness of the wick proximate to an output end of the chamber. In embodiments, the condensate 114 within the wick 106 that is disposed along the evaporator chamber floor 104b may be heated by heat conducted from the processor 110 to the evaporator chamber floor 104b. In embodiments, the condensate 114 may begin to boil and vaporize, forming the vapor 116 that may fill the vapor chamber 115. The greater thickness of the wick 106 proximate to the input end 112a as compared to the thickness of the wick 106 proximate to the output end 118a my cause greater vapor pressure to build within the vapor chamber 115.

At block 608, the process may include expelling vapor outflow from the output end of the chamber. In embodiments, the greater volume of the vapor chamber 115 that is proximate to the output end 118a, the greater pressure in the vapor chamber 115, and/or the greater diameter of the output pipe 118 in relation to the input pipe 112 may facilitate the expelling of the vapor 116 as vapor outflow from the output end 118a.

Various operations are described as multiple discrete operations in turn, in a manner that is most helpful in understanding the claimed subject matter. However, the order of description should not be construed as to imply that these operations are necessarily order dependent.

### Examples

Example 1 may be a cooling apparatus, comprising: an evaporator that includes a chamber to receive a condensate inflow from an input end, and output a vapor outflow at an output end; a wick disposed within the chamber, to receive condensate from the input end, wherein a thickness of the wick proximate to the input end is greater than a thickness of the wick proximate to the output end; and wherein the wick is to cause condensate within the wick to be vaporized by heat conducted from a surface of the chamber, and the resulting vapor to be expelled from the chamber as the vapor outflow.

Example 2 may include the cooling apparatus of example 1, wherein the wick has a variable thickness.

Example 3 may include the cooling apparatus of example 2, wherein the variable thickness is a gradient from the input end to the output end.

Example 4 may include the cooling apparatus of example 1, wherein the vapor and condensate are water, R245fa, or methanol.

Example 5 may include the cooling apparatus of example 1, wherein the input end and the output end are connected by a heat pipe.

Example 6 may include the cooling apparatus of example 5, wherein the heat pipe is a loop heat pipe.

Example 7 may include the cooling apparatus of example 6, wherein the evaporator and loop heat pipe form a closed system, wherein the closed system has a single wick in the chamber.

Example 8 may include the cooling apparatus of example 5, wherein the heat pipes are approximately 4 millimeters in diameter, and have at least a 300 watt capacity.

Example 9 may include the cooling apparatus of example 5, wherein the heat pipe and chamber are under a vacuum.

Example 10 may include the cooling apparatus of example 5, wherein the heat pipe has a diameter of less than 6 millimeters (mm).

Example 11 may include the cooling apparatus of example 7, wherein the closed system has a single wick in the chamber.

Example 12 may include the cooling apparatus of example 5, wherein a segment of a heat pipe proximate to the input end has a diameter that is less than a segment of a heat pipe proximate to the output end to facilitate the vapor outflow.

Example 13 may include the cooling apparatus of example 5, wherein the vapor outflow is due in part to vapor pressure created by boiling condensate.

Example 14 may include the cooling apparatus of example 13, wherein the cooling apparatus is operationally independent of its orientation with respect to gravity.

Example 15 may include the cooling apparatus of any one of examples 1-14, wherein the thickness of the wick gets thinner from the wick proximate to the input end to the wick proximate to the output end.

Example 16 may include the cooling apparatus of any one of examples 1-14, wherein the wick is disposed proximate to the surface of the chamber.

Example 17 may include the cooling apparatus of any one of examples 1-14, wherein the wick substantially covers the surface of the chamber.

Example 18 may include the cooling apparatus of any one of examples 1-14, wherein the surface is a bottom surface of the evaporator chamber.

Example 19 may include the cooling apparatus of any one of examples 1-14, wherein the wick is a sintered material.

Example 20 may include the cooling apparatus of any one of examples 1-14, further comprising a condenser that includes a plurality of fins coupled to the evaporator to dissipate heat from the evaporator.

Example 21 may include the cooling apparatus of example 20, wherein the plurality of fins are oriented in multiple directions.

Example 22 may include the cooling apparatus of example 20, wherein the plurality of fins are disposed above the evaporator.

Example 23 may include the cooling apparatus of example 20, further comprising a heat source thermally coupled to the evaporator.

Example 24 may include the cooling apparatus of example 23, wherein the heat source is a reduced-thickness heat sink to reduce weight or increase thermal performance of the cooling apparatus.

Example 25 may include the cooling apparatus of any examples 1-14, further comprising a condenser thermally coupled to the evaporator that includes a plurality of fins to dissipate heat from the evaporator.

Example 26 may include the cooling apparatus of example 25, wherein the plurality of fins are thermally coupled to the heat pipe to route heat through the plurality of fins for dissipation.

Example 27 may include the cooling apparatus of example 26, wherein the plurality of fins thermally coupled to the heat pipe are further to cause vapor within the heat pipe to condense.

Example 28 may include the cooling apparatus of example 26, wherein the heat pipe is soldered onto one or more of the plurality of fins.

Example 29 may include the cooling apparatus of example 25, wherein the plurality of fins are oriented in multiple directions.

Example 30 may include the cooling apparatus of example 25, wherein the plurality of fins are disposed above the evaporator.

Example 31 may include the cooling apparatus of example 30, wherein one or more of the plurality of fins are disposed above one or more elements attached to a motherboard.

Example 32 may include the cooling apparatus of example 31, wherein the one or more elements further include dual in-line memory modules (DIMM) or voltage regulators (VR).

Example 33 may include the cooling apparatus of example 31, wherein one or more of the plurality of fins is to support additional vertical fins above the one or more elements.

Example 34 may include the cooling apparatus of example 33, wherein one or more of the plurality of fins is a Y-shaped fin of determined thickness.

Example 35 may include the cooling apparatus of example 25, further comprising a heat source thermally coupled to the evaporator.

Example 36 may include the cooling apparatus of example 35, wherein the heat source is a heat sink compact form, one or more microchannel plates, or one or more electrical components.

Example 37 may include the cooling apparatus of example 35, wherein the condenser, evaporator, and heat source are a rigidly coupled unit.

Example 38 may include the cooling apparatus of example 37, wherein the heat source is a processor.

Example 39 may include the cooling apparatus of example 38, wherein the condenser and the evaporator maintain a keep out volume (KOV) for the processor.

Example 40 may include the cooling apparatus of example 39, wherein thermal performance of the cooling apparatus exceeds thermal performance of a 2U heat pipe heat sink having a similar KOV.

Example 41 may include the cooling apparatus of example 38, wherein the cooling apparatus meets thermal requirements of the processor.

Example 42 may include the cooling apparatus of example 37, wherein the processor may be inserted onto a motherboard by inserting the rigidly coupled unit onto the motherboard.

Example 43 may include the cooling apparatus of example 42, wherein the rigidly coupled unit is a processor heatsink loading mechanism (PHLM).

Example 44 may include the cooling apparatus of example 41, wherein the cooling apparatus meets thermal requirements of the processor without impacting a board level component layout on a motherboard.

Example 45 may include the cooling apparatus of example 25, wherein a heat source is a reduced-thickness heat sink to reduce weight or increase thermal performance of the cooling apparatus.

Example 46 may include the cooling apparatus of example 25, wherein the evaporator chamber further includes a plurality of evaporator chambers with a plurality of chamber walls that extend from a top surface of the evaporator to a bottom surface of the evaporator.

Example 47 may include the cooling apparatus of example 46, wherein the plurality of chamber walls are to provide structural rigidity to the evaporator.

Example 48 may include the cooling apparatus of example 46, wherein the plurality of chamber walls may include copper, brass, stainless steel, or other heat conducting metal or alloy.

Example 49 may include the cooling apparatus of example 46, comprising a surface area of a face of a heat source that is substantially adjacent to a total area of the surfaces of the plurality of evaporator chambers; and wherein the surface area of the face of the heat source is substantially equal to the total area of the surfaces of the plurality of evaporator chambers.

Example 50 may include the cooling apparatus of example 49, wherein the surfaces of the plurality of evaporator chambers are substantially covered with the wick, wherein the heat source is a multi-core processor (MCP), and wherein the surface area of the face of the heat source is proximate to a plurality of cores of the MCP.

Example 51 may include the cooling apparatus of example 50, wherein the heat source is a processor.

Example 52 may include the cooling apparatus of example 50, wherein the cooling apparatus meets heat flux requirements for the heat source.

Example 53 may include the cooling apparatus of example 50, wherein the cooling apparatus has a heat dissipation capacity based upon the condenser.

Example 54 may include the cooling apparatus of example 25, wherein the cooling apparatus is coupled to a processor that is seated on a circuit board.

Example 55 may include the cooling apparatus of example 54, wherein the circuit board is coupled to a mechanism to facilitate use in a rackmount system.

Example 56 may include the cooling apparatus of example 55, wherein the circuit board is inserted into the rackmount system.

Example 57 may be a method for cooling, the method comprising: receiving condensate from an input end of a chamber of an evaporator to a portion of a wick disposed on a surface of the chamber proximate to the input end; conducting heat from the surface of the chamber to the wick; vaporizing the condensate in the wick, wherein a thickness of the wick proximate to the input end is greater than a thickness of the wick proximate to an output end of the chamber; and expelling vapor outflow from the output end of the chamber.

Example 58 may include the method of example 57, wherein the vapor and condensate are water, R245fa, or methanol.

Example 59 may include the method of example 57, wherein the input end and the output end are connected by a heat pipe, and wherein the chamber, the input end, the output end, and the heat pipe are a closed system.

Example 60 may include the method of example 59, wherein the heat pipe and chamber are under a vacuum.

Example 61 may include the method of example 59, wherein the closed system has a single wick in the chamber.

Example 62 may include the method of example 59, wherein a segment of a heat pipe proximate to the input end has a diameter that is less than a segment of a heat pipe proximate to the output end, to facilitate the vapor outflow.

Example 63 may include the method of example 59, wherein the vapor travels from the output end through the heat pipe toward the input end due in part to vapor pressure created by boiling condensate.

Example 64 may include the method of example 63, wherein the method is operationally independent of an orientation of the closed system with respect to gravity.

Example 65 may include the method of any one of examples 57-64, wherein the thickness of the wick increases from the wick proximate to a condensate inflow to the wick proximate to the vapor outflow.

Example 66 may include the method of any one of examples 57-64, wherein the wick is disposed proximate to the surface of the chamber.

Example 67 may include the method of any one of examples 57-64, wherein the wick substantially covers the surface of the chamber.

Example 68 may include the method of any one of examples 59-64, further comprising: condensing the vapor into a condensate by passing the vapor through a heat pipe thermally coupled to a condenser, wherein the condenser includes a plurality of fins to dissipate heat from the evaporator.

Example 69 may include the method of example 68, wherein the heat pipe is soldered to one or more of the plurality of fins.

Example 70 may include the method of any one of examples 59-64, further comprising: conducting heat from a heat source to the surface of the chamber, wherein the heat source is a processor, a heat sink compact form, one or more microchannel plates, or one or more electrical components.

Example 71 may include the method of example 70, wherein the method meets heat flux requirements for the heat source.

Example 72 may be an apparatus for cooling, the apparatus comprising: means for receiving condensate from an input end of a chamber of an evaporator to a portion of a wick disposed on a surface of the chamber proximate to the input end; means for conducting heat from the surface of the chamber to the wick; means for vaporizing the condensate in the wick, wherein a thickness of the wick proximate to the input end is greater than a thickness of the wick proximate to an output end of the chamber; and means for expelling vapor outflow from the output end of the chamber.

Example 73 may include the apparatus of example 72, wherein the vapor and condensate are water, R245fa, or methanol.

Example 74 may include the apparatus of example 72, wherein the input end and the output end are connected by a heat pipe, and wherein the chamber, the input end, the output end, and the heat pipe are a closed system.

Example 75 may include the apparatus of example 74, wherein the heat pipe and chamber are under a vacuum.

Example 76 may include the apparatus of example 74, wherein the closed system has a single wick in the chamber.

Example 77 may include the apparatus of example 74, wherein a segment of a heat pipe proximate to the input end has a diameter that is less than a segment of a heat pipe proximate to the output end, wherein a difference in diameter between the segment proximate to the input end and the segment proximate to the output end is to facilitate the vapor outflow.

Example 78 may include the apparatus of example 74, wherein the vapor travels from the output end through the heat pipe toward the input end due in part to vapor pressure created by boiling condensate.

Example 79 may include the apparatus of example 78, wherein the apparatus is operationally independent of an orientation of the closed system with respect to gravity.

Example 80 may include the apparatus of any examples 72-79, wherein the thickness of the wick graduates from the wick proximate to a condensate inflow to the wick proximate to the vapor outflow.

Example 81 may include the apparatus of any one of examples 72-79, wherein the wick is disposed proximate to the surface of the chamber.

Example 82 may include the apparatus of any examples 72-79, wherein the wick substantially covers the surface of the chamber.

Example 83 may include the apparatus of any one of examples 74-79, further comprising: means for condensing the vapor into a condensate by passing the vapor through a heat pipe thermally coupled to a condenser, wherein the condenser includes a plurality of fins to dissipate heat from the evaporator.

Example 84 may include the apparatus of example 83, wherein the heat pipe is soldered to one or more of the plurality of fins.

Example 85 may include the apparatus of any one of examples 74-79, further comprising: conducting heat from a heat source to the surface of the chamber, wherein the heat source is a processor, a heat sink compact form, one or more microchannel plates, or one or more electrical components.

Example 86 may include the apparatus of example 85, wherein the method meets heat flux requirements for the heat source.

The foregoing description of one or more implementations provides illustration and description, but is not intended to be exhaustive or to limit the scope of the embodiments to the precise form disclosed or claimed herein. Modifications and variations are possible in light of the above teachings or may be acquired from practice of various implementations of the various embodiments. Future improvements, enhancements, or changes to particular components, methods, or means described in the various embodiments are contemplated to be within the scope of the claims and embodiments described herein, as would readily be understood by a person having ordinary skill in the art.

What is claimed is:

1. A cooling apparatus, comprising:
an evaporator that includes a chamber to receive a condensate inflow from an input end, and output a vapor outflow at an output end;
a wick disposed within the chamber, to receive condensate from the input end, wherein a thickness of the wick proximate to the input end is greater than a thickness of the wick proximate to the output end; and
wherein the wick is to cause condensate within the wick to be vaporized by heat conducted from a surface of the chamber, and the resulting vapor to be expelled from the chamber as the vapor outflow.

2. The cooling apparatus of claim 1, wherein the wick has a variable thickness.

3. The cooling apparatus of claim 2, wherein the variable thickness is a gradient from the input end to the output end.

4. The cooling apparatus of claim 1, wherein the vapor and condensate are water, R245fa, or methanol.

5. The cooling apparatus of claim 1, wherein the input end and the output end are connected by a heat pipe.

6. The cooling apparatus of claim 5, wherein the heat pipe is a loop heat pipe.

7. The cooling apparatus of claim 6, wherein the evaporator and loop heat pipe form a closed system, wherein the closed system has a single wick in the chamber.

8. The cooling apparatus of claim 1, wherein the wick is disposed proximate to the surface of the chamber.

9. The cooling apparatus of claim 1, wherein the wick substantially covers the surface of the chamber.

10. The cooling apparatus of claim 1, wherein the surface is a bottom surface of the evaporator chamber.

11. The cooling apparatus of claim 1, wherein the wick is a sintered material.

12. The cooling apparatus of claim 1, further comprising a condenser thermally coupled to the evaporator that includes a plurality of fins to dissipate heat from the evaporator.

13. The cooling apparatus of claim 12, wherein the plurality of fins are thermally coupled to the heat pipe to route heat through the plurality of fins for dissipation.

14. The cooling apparatus of claim 13, wherein the heat pipe is soldered onto one or more of the plurality of fins.

15. The cooling apparatus of claim 12, further comprising a heat source thermally coupled to the evaporator.

16. The cooling apparatus of claim 15, wherein the heat source is a heat sink compact form, one or more microchannel plates, or one or more electrical components.

17. The cooling apparatus of claim 15, wherein the condenser, evaporator, and heat source are a rigidly coupled unit.

18. The cooling apparatus of claim 12, wherein the evaporator chamber further includes a plurality of evaporator chambers with a plurality of chamber walls that extend from a top surface of the evaporator to a bottom surface of the evaporator.

19. The cooling apparatus of claim 18, wherein the plurality of chamber walls are to provide structural rigidity to the evaporator.

20. The cooling apparatus of claim 18, comprising a surface area of a face of a heat source that is substantially adjacent to a total area of the surfaces of the plurality of evaporator chambers; and
wherein the surface area of the face of the heat source is substantially equal to the total area of the surfaces of the plurality of evaporator chambers.

21. The cooling apparatus of claim 12, wherein the cooling apparatus is coupled to a processor that is seated on a circuit board.

22. The cooling apparatus of claim 21, wherein the circuit board is coupled to a mechanism to facilitate use in a rackmount system.

23. The cooling apparatus of claim 22, wherein the circuit board is inserted into the rackmount system.

24. A method for cooling, the method comprising:
receiving condensate from an input end of a chamber of an evaporator to a portion of a wick disposed on a surface of the chamber proximate to the input end;
conducting heat from the surface of the chamber to the wick;
vaporizing the condensate in the wick, wherein a thickness of the wick proximate to the input end is greater than a thickness of the wick proximate to an output end of the chamber; and
expelling vapor outflow from the output end of the chamber.

25. The method of claim 24, wherein the input end and the output end are connected by a heat pipe, and wherein the chamber, the input end, the output end, and the heat pipe are a closed system.
